(19) United States
(12) Patent Application Publication
(10) Pub. No.: US 2026/0293537 A1
(43) Pub. Date: Sep. 24, 2026

(54) RESISTIVE RANDOM ACCESS MEMORY DEVICE

(71) Applicant: UNITED MICROELECTRONICS CORP., Hsin-Chu City (TW)

(72) Inventor: Hui-Lin Wang, Taipei City (TW)

(73) Assignee: UNITED MICROELECTRONICS CORP., Hsin-Chu City (TW)

(21) Appl. No.: 19/186,602

(22) Filed: Apr. 22, 2025

(30) Foreign Application Priority Data
Mar. 24, 2025 (TW) 114110936

(51) Int. Cl. H10N 70/00; H10B 63/00; H10N 70/20

(52) U.S. Cl. CPC H10N 70/841; H10B 63/80; H10N 70/063; H10N 70/24

(57) ABSTRACT

A resistive random access memory (RRAM) includes an interlayer dielectric (ILD) layer on a substrate, a contact plug in the ILD layer, a bottom electrode on the contact plug, a resistor switching layer on the bottom electrode, and a top electrode (TE) on the resistor switching layer. Preferably, the TE includes more than one TE and the more than one TE includes titanium nitride (TiN).

### BACKGROUND OF THE INVENTION

### 1 FIELD OF THE INVENTION

The invention relates to a semiconductor device, and more particularly to a resistive random access memory (RRAM) device.

### 2 DESCRIPTION OF THE PRIOR ART

Non-volatile memory devices have the advantages of retaining data even if the electrical power is being cut off, hence non-volatile memory devices have been widely used in most appliances today for maintaining proper operation of the electronic products. Currently, a popular non-volatile memory device being developed today is referred to as resistive random access memory (RRAM), which has the advantages of low voltage and short erase time under write operation, long memory duration, no damage under read operation, multiphase memory, simple structure, and small size. With all these benefits, RRAM devices are likely to be used in various personal computers and electronic equipment in the coming future.

In integrated circuits, RRAM is a merging technology applied for the next generation non-volatile memory devices. Specifically, RRAM is a memory structure having a resistive random access memory array, in which each of the resistive random access memory units uses resistance values to store one bit of data instead of electrical potentials. In particular, each of the resistive random access memory units include a resistance material layer that could be used to adjust resistance value for demonstrating “0” or “1”.

One approach to optimize RRAM array is to minimize its size as much as possible. Nevertheless, as size of the device decrease, fabrication cost and complexity also increase accordingly. Hence, how to lower the overall cost while maintaining yield of the product has become a major challenge in this field.

### SUMMARY OF THE INVENTION

According to an embodiment of the present invention, a resistive random access memory (RRAM) includes an interlayer dielectric (ILD) layer on a substrate, a contact plug in the ILD layer, a bottom electrode on the contact plug, a resistor switching layer on the bottom electrode, and a top electrode (TE) on the resistor switching layer. Preferably, the TE comprises more than one TE and the more than one TE comprises titanium nitride (TiN).

According to another aspect of the present invention, a resistive random access memory (RRAM) includes an interlayer dielectric (ILD) layer on a substrate, a contact plug in the ILD layer, a bottom electrode on the contact plug, a resistor switching layer on the bottom electrode, and a top electrode (TE) on the resistor switching layer. Preferably, the top electrode includes titanium nitride (TiN) having a gradient concentration of nitrogen.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-7 illustrate a method for fabricating a semiconductor device according to an embodiment of the present invention.

FIG. 8 illustrates a structural view of a semiconductor device according to an embodiment of the present invention.

FIG. 9 illustrates a structural view of a semiconductor device according to an embodiment of the present invention.

FIG. 10 illustrates a structural view of a semiconductor device according to an embodiment of the present invention.

FIG. 11 illustrates a structural view of a semiconductor device according to an embodiment of the present invention.

### DETAILED DESCRIPTION

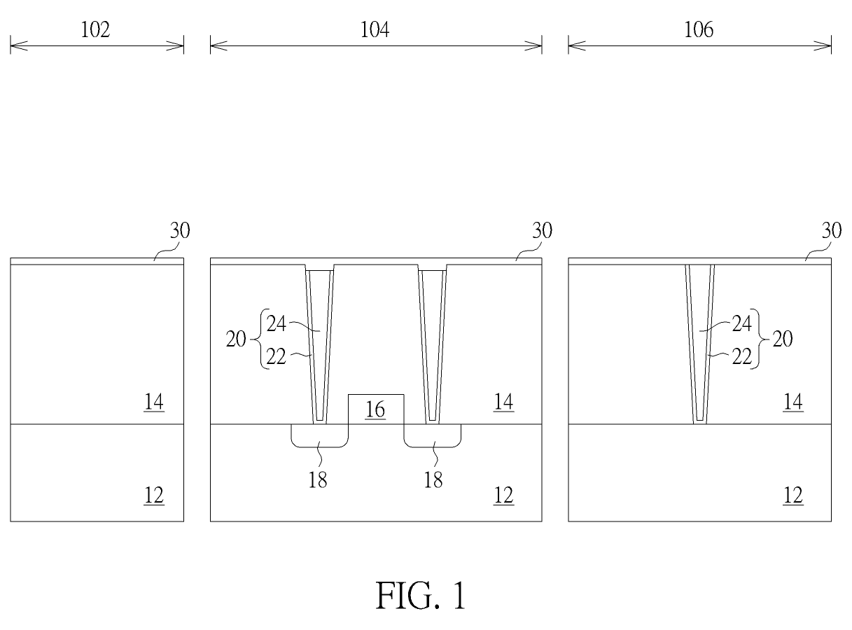

Referring to FIGS. 1-7, FIGS. 1-7 illustrate a method for fabricating a semiconductor device, or more specifically a RRAM device according to an embodiment of the present invention. As shown in FIG. 1, a substrate 12 made of semiconductor material is first provided, in which the semiconductor material could be selected from the group consisting of silicon (Si), germanium (Ge), Si-Ge compounds, silicon carbide (SiC), and gallium arsenide (GaAs), and an alignment mark (AM) region 102, a RRAM region 104, and a logic region 106 are defined on the substrate 12.

Active devices such as metal-oxide semiconductor (MOS) transistors, passive devices, conductive layers, and interlayer dielectric (ILD) layer 14 could also be formed on top of the substrate 12 on both RRAM region 104 and logic region 106. More specifically, planar MOS transistors or non-planar (such as FinFETs) MOS transistors could be formed on the substrate 12, in which the MOS transistors could include transistor elements such as gate structures 16 (for example metal gates) and source/drain regions 18, spacer, epitaxial layer, and contact etch stop layer (CESL). The ILD layer 14 could be formed on the substrate 12 to cover the MOS transistors, and a plurality of contact plugs 20 could be formed in the ILD layer 14 to electrically connect to the gate structures 16 and/or source/drain regions 18 of MOS transistors. Since the fabrication of planar or non-planar transistors and ILD layer is well known to those skilled in the art, the details of which are not explained herein for the sake of brevity.

In this embodiment, the formation of the contact plugs 20 could be accomplished by first conducting a pattern transfer process by using a patterned mask (not shown) as mask to remove part of the ILD layer 14 on the memory region 102 and logic region 104 for forming contact holes (not shown) exposing the source/drain regions 18 underneath. Next, metal or conductive materials including a barrier layer 22 selected from the group consisting of titanium (Ti), titanium nitride (TiN), tantalum (Ta), and tantalum nitride (TaN) and a metal layer 24 selected from the group consisting of tungsten (W), copper (Cu), aluminum (Al), titanium aluminide (TiAl), and cobalt tungsten phosphide (CoWP) are deposited into the contact holes, and then a planarizing process such as chemical mechanical polishing (CMP) process is conducted to remove part of the metal for forming contact plugs 20 or metal interconnections in the contact holes electrically connecting the source/drain regions 18.

Next, another pattern transfer process could be conducted by using a patterned mask to remove part of the contact plugs 20 for forming a recess directly on top of each contact plug 20 while the top surface of the remaining contact plugs 20 is slightly lower than the top surface of the ILD layer 14 on two adjacent sides. Next, a bottom electrode (BE) 30 is formed on the ILD layer 14 on the AM region 102, the RRAM region 104, and the logic region 106 and filling the recesses directly atop the contact plugs 20 completely. In this embodiment, the bottom electrode 30 is made of metal nitride such as tantalum nitride (TaN) and the thickness thereof is between 100-200 Angstroms.

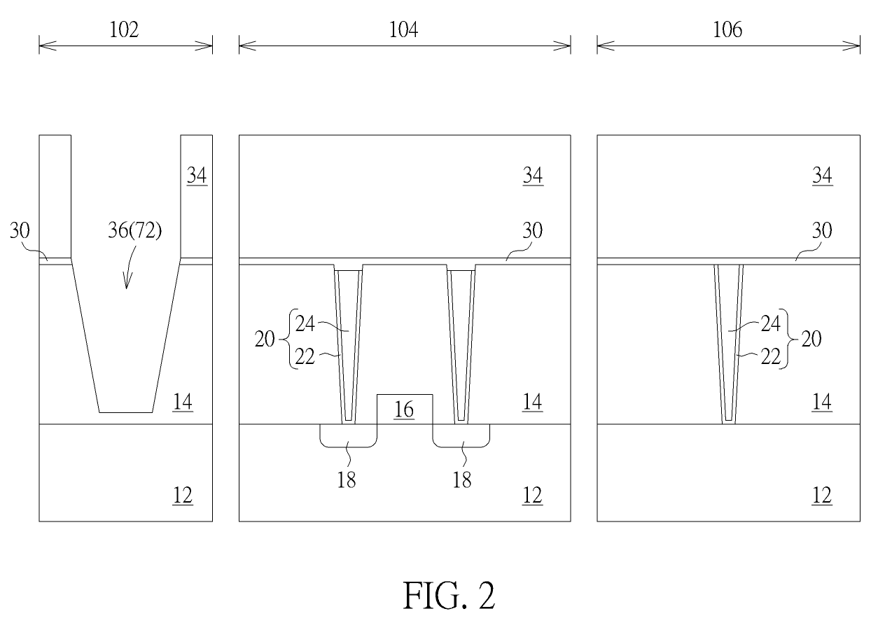

Next, as shown in FIG. 2, a patterned mask 34 such as patterned resist is formed on the bottom electrode 30 of the AM region 102, the RRAM region 104, and the logic region 106, in which the patterned mask 34 includes an opening exposing the surface of the bottom electrode 30 on the AM region 102. Next, an etching process is conducted by using the patterned mask 34 as mask to remove part of the bottom electrode 30 and part of the ILD layer 14 on the AM region 102 for forming a trench 36, in which the trench 36 could be used as an alignment mark 72 on the AM region 102 in the later process.

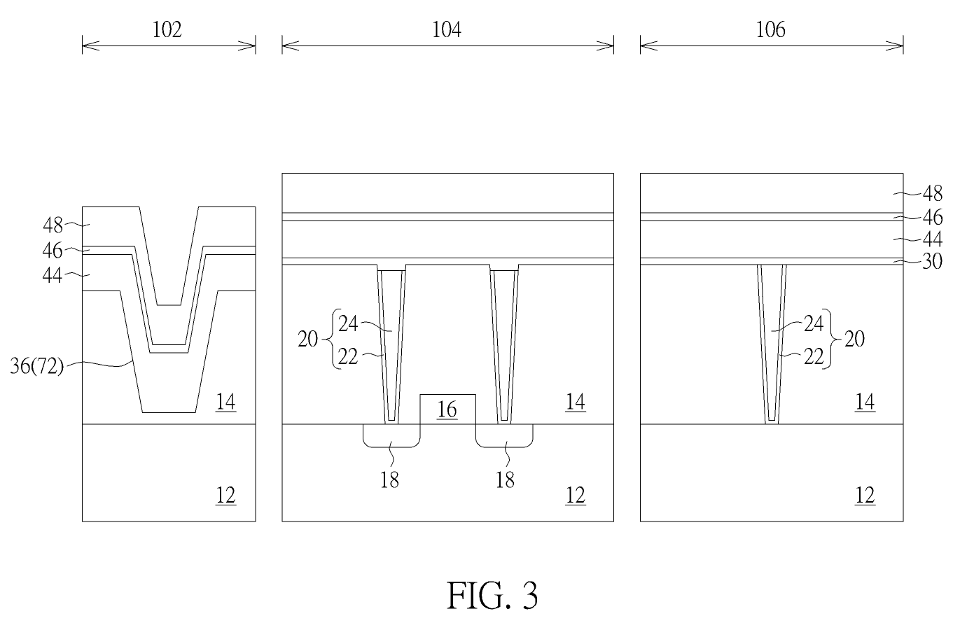

Next, as shown in FIG. 3, the patterned mask 34 is stripped by oxygen gas to expose the bottom electrode 30 once more, and then a resistor switching layer 44, a capping layer 46, and a top electrode (TE) 48 are formed on the surface of bottom electrode 30. In this embodiment, the resistor switching layer 44 preferably includes a metal nitride layer such as TaO or hafnium oxide (HfO₂), the capping layer 46 includes metal such as iridium (Ir), and the top electrode 48 includes metal nitride such as TiN. Preferably, the top electrode 48 is made of a single layer structure, the top electrode 48 is a nitrogen-rich layer, nitrogen concentration or atomic percentage of the top electrode 48 is between 30~60 at%, and the top electrode 48 does not include a gradient concentration of nitrogen. In other words, any spot within the top electrode 48 has equal nitrogen content or concentration or that the nitrogen concentration of the entire layer is evenly distributed.

It should be noted that after the patterned mask 34 is stripped and before the resistor switching layer 44 is formed, a selective pre-clean process could be conducted by using argon (Ar) plasma to remove metal oxide layer formed during stripping of the patterned mask 34, and then a planarizing process such as chemical mechanical polishing (CMP) process is conducted to remove part of the ILD layer 14 and all the bottom electrode 30 on the AM region 102 as well as part of the bottom electrode 30 on the RRAM region 104 and logic region 106. The thickness of the bottom electrode 30 remained after the planarizing process is between 50-100 Angstroms.

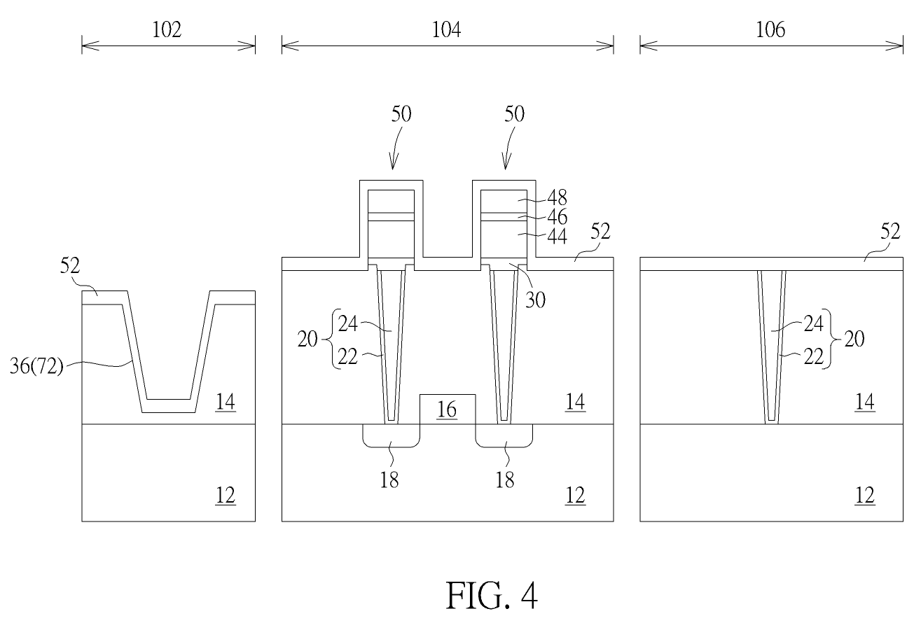

Next, as shown in FIG. 4, one or more etching processes could be conducted by using a patterned mask (not shown) as mask to remove all the top electrode 48, all the capping layer 46, all the resistor switching layer 44, and all the bottom electrode 30 on the AM region 102 and logic region 106 and part of the top electrode 48, part of the capping layer 46, part of resistor switching layer 44, and part of the bottom electrode 30 on the RRAM region 104. This exposes the surface of the ILD layer 14 on the AM region 102 and logic region 106 and forms a RRAM 50 made of patterned bottom electrode 30, patterned resistor switching layer 44, patterned capping layer 46, and patterned top electrode 48 on the RRAM region 104. Next, a cap layer 52 is formed on the surface of the ILD layer 14 and into the trench 36 on the AM region 102, surface of the ILD layer 14 and RRAM 50 on the RRAM region 104, and surface of the ILD layer 14 on the logic region 106.

It should be noted that when part of the top electrode 48, part of the capping layer 46, part of the resistor switching layer 44, and part of the bottom electrode 30 are patterned to form the RRAM 50, it would be desirable to remove part of the ILD layer 14 adjacent to two sides of the RRAM 50 so that the top surface of the remaining ILD layer 14 is slightly lower than the bottom surface of the bottom electrode 30 or even lower than the top surface of the contact plugs 20. By doing so, the bottom surface of the cap layer 52 adjacent to two sides of the RRAM 50 afterwards could then be adjusted according to the height of the ILD layer 14. For instance, the bottom surface of the cap layer 52 adjacent to two sides of the RRAM 50 could be even with or slightly lower than the bottom surface of the bottom electrode 30 or lower than the top surface of the contact plugs 20, which are all within the scope of the present invention.

Preferably, the cap layer 52 includes dielectric material such as silicon oxycarbide (SiOC), silicon carbon nitride (SiCN), or silicon nitride (SiN) and the etching process conducted for forming the aforementioned RRAM 50 during patterning process could include reactive ion etching (RIE) or ion beam etching (IBE) process, but not limited thereto.

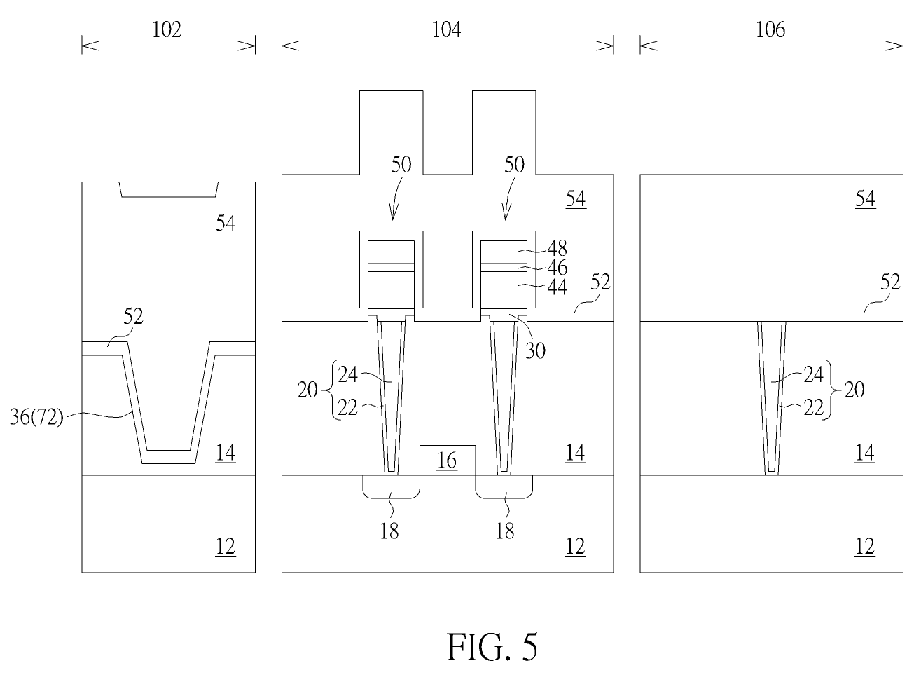

Next, as shown in FIG. 5, a flowable chemical vapor deposition (FCVD) process could be conducted to form an inter-metal dielectric (IMD) layer 54 on ILD layer 14 on the AM region 102, the RRAM region 104, and the logic region 106 to fill the trench 36 completely and cover the RRAM 50. In this embodiment, the IMD layer 54 is preferably made of silicon oxide or ultra low-k (ULK) dielectric layer including but not limited to for example porous material or silicon oxycarbide (SiOC) or carbon doped silicon oxide (SiOCH).

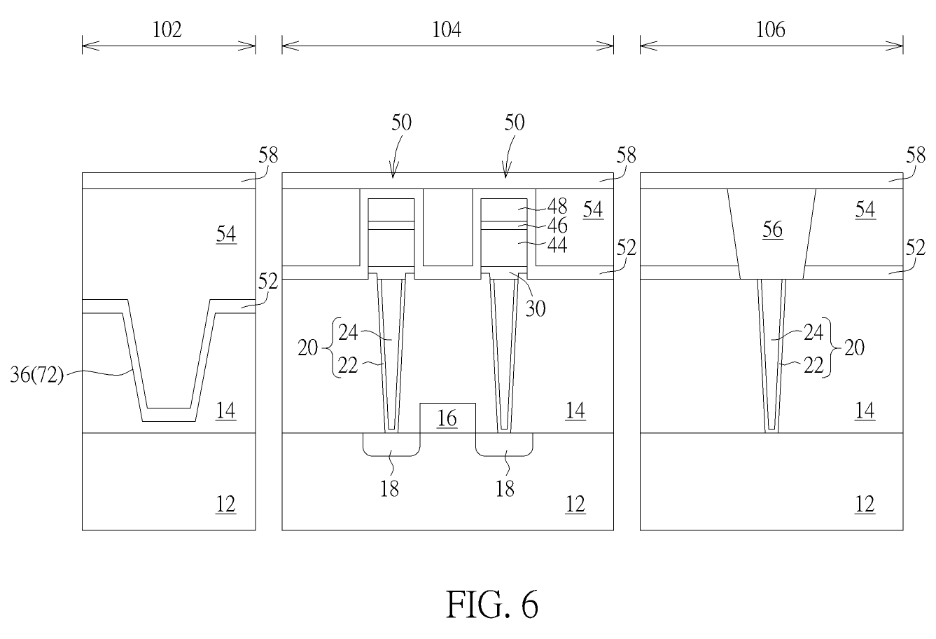

Next, as shown in FIG. 6, a planarizing process such as CMP is conducted to remove part of the IMD layer 54 on the AM region 102, RRAM region 104, and logic region 106 so that the top surfaces of the IMD layer 54 and the cap layer 52 on the RRAM region 104 are coplanar.

Next, a patterned transfer process could be conducted by using a patterned mask (not shown) as mask to remove part of the IMD layer 54 and part of the cap layer 52 on the and logic region 106 for forming a contact hole (not shown) exposing the contact plug 20 underneath. Next, metal or conductive materials including a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP) are deposited into the contact hole, and then a planarizing process such as CMP process is conducted to remove part of the metals for forming a contact plug or metal interconnection 56 in the contact hole electrically connecting the contact plug 20 underneath. Next, a stop layer 58 is formed on the IMD layer 54 on the AM region 102, the RRAM region 104, and the logic region 106. Preferably, the stop layer 58 is made of nitrogen doped carbide (NDC), silicon nitride, silicon carbon nitride (SiCN), silicon oxynitride (SiON), or combination thereof.

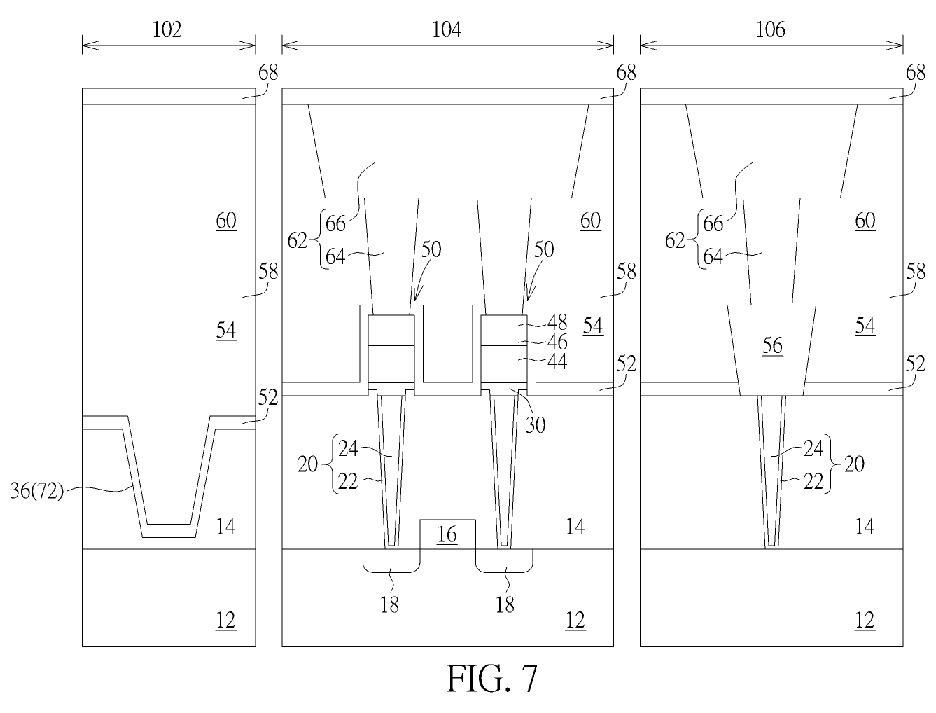

Next, as shown in FIG. 7, another IMD layer 60 is formed on the surface of the stop layer 58 and one or more photo-etching process is conducted to remove part of the IMD layer 60, part of the stop layer 58, and part of the cap layer 52 on the RRAM region 104 and logic region 106 to form contact holes (not shown) exposing the top electrode 48 and metal interconnection 56. Next, conductive materials are deposited into the contact holes and a planarizing process such as CMP is conducted to form a metal interconnection 62 connecting the top electrode 48 and metal interconnection 56 underneath, and another stop layer 68 is formed on the surface of the metal interconnections 62 thereafter. Similar to the aforementioned metal interconnection 56, the metal interconnections 62 could be embedded within the IMD layer 60 according to a single damascene process or dual damascene process. For instance, each of the metal interconnections 62 on the RRAM region 104 and logic region 106 could further include via conductors 64 connecting the RRAM 50 and metal interconnection 56 underneath and a trench conductor 66 atop the via conductors 64. Moreover, each of the metal interconnections 62 could further include a barrier layer and a metal layer, in which the barrier layer could be selected from the group consisting of titanium (Ti), titanium nitride (TiN), tantalum (Ta), and tantalum nitride (TaN) and the metal layer could be selected from the group consisting of tungsten (W), copper (Cu), aluminum (Al), titanium aluminide (TiAl), and cobalt tungsten phosphide (CoWP).

In this embodiment, the IMD layer 60 preferably include an ultra low-k (ULK) dielectric layer including but not limited to for example porous material or silicon oxycarbide (SiOC) and the stop layer 68 preferably includes nitrogen doped carbide (NDC), silicon nitride (SiN), silicon carbon nitride (SiCN), or combination thereof and most preferably includes SiN. This completes the fabrication of a semiconductor device according to an embodiment of the present invention.

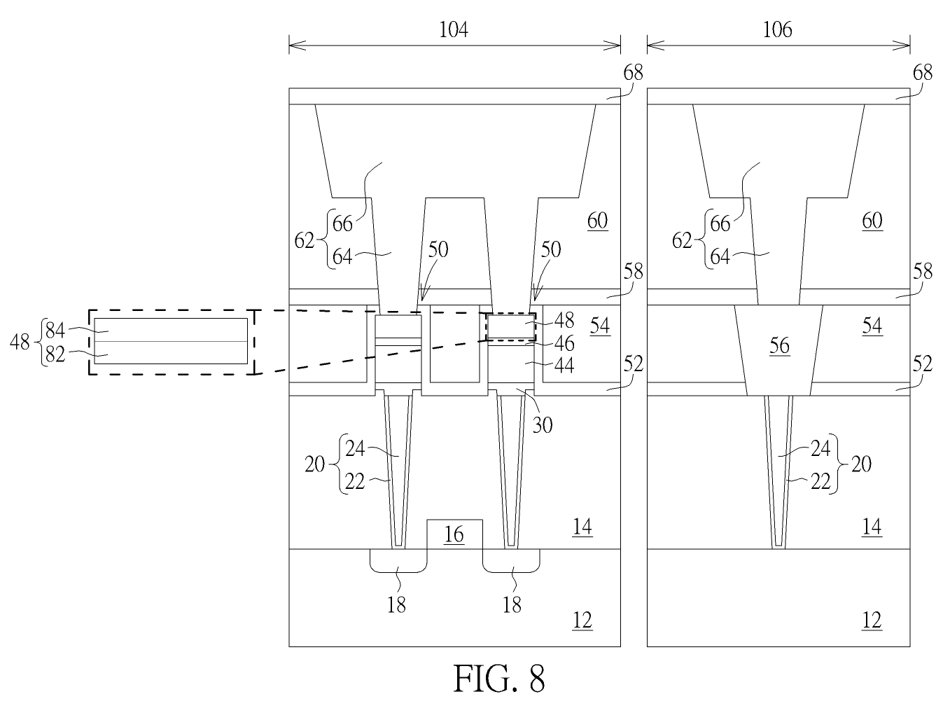

Referring to FIG. 8, FIG. 8 illustrates a structural view of a semiconductor device according to an embodiment of the present invention. For simplicity purpose and to emphasize various embodiment of the top electrode 48, elements on the AM region 102 are omitted in this embodiment and embodiments afterwards. As shown in FIG. 8, in contrast to the top electrode 48 from the previous embodiment is made of a single layer structure, the top electrode 48 could also be made of more than one layer such as a dual layer structure made of a first TE 82 and a second TE 84, in which the bottom first TE 82 directly contacting the capping layer 46 includes metal nitride such as TiN, the top second TE 84 includes metal such as Ti, and the first TE 82 and second TE 84 could include same thickness or different thickness. Similar to the top electrode 48 shown in FIG. 7, the first TE 82 in this embodiment is a nitrogen-rich layer, nitrogen concentration of the first TE 82 is between 30~60 at%, and the first TE 82 does not include a gradient concentration of nitrogen. In other words, any spot within the first TE 82 has equal nitrogen content or concentration or that the nitrogen concentration of the entire layer is evenly distributed.

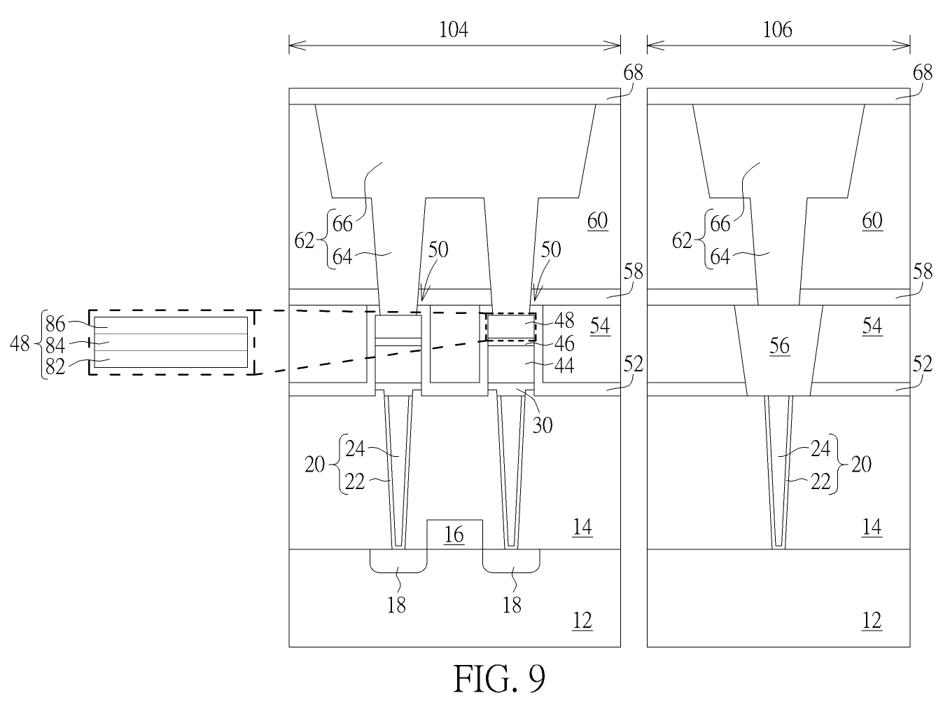

Referring to FIG. 9, FIG. 9 illustrates a structural view of a semiconductor device according to an embodiment of the present invention. As shown in FIG. 9, in contrast to the top electrode 48 in the aforementioned embodiments are made of a single layer or dual layer structure, the top electrode 48 could also be made of a triple layer structure including a first TE 82 disposed on the capping layer 46, a second TE 84 disposed on the first TE 82, and a third TE 86 disposed on the second TE 84. In this embodiment, the bottom first TE 82 directly contacting the capping layer 46 includes metal nitride such as TiN, the middle second TE 84 includes metal such as Ti, and the top third TE 86 also includes metal nitride such as TiN, in which the first TE 82, the second TE 84, and the third TE 86 could include same thickness or different thickness.

Similar to the top electrode 48 shown in FIG. 7, each of the first TE 82 and the third TE 86 is a nitrogen-rich layer, the nitrogen concentration of each of the first TE 82 and the third TE 86 is between 30~60 at%, and both the first TE 82 and the third TE 86 do not include a gradient concentration of nitrogen. In other words, any spot within the first TE 82 and third TE 86 has equal nitrogen content or concentration or that the nitrogen concentration of the entire layer is evenly distributed.

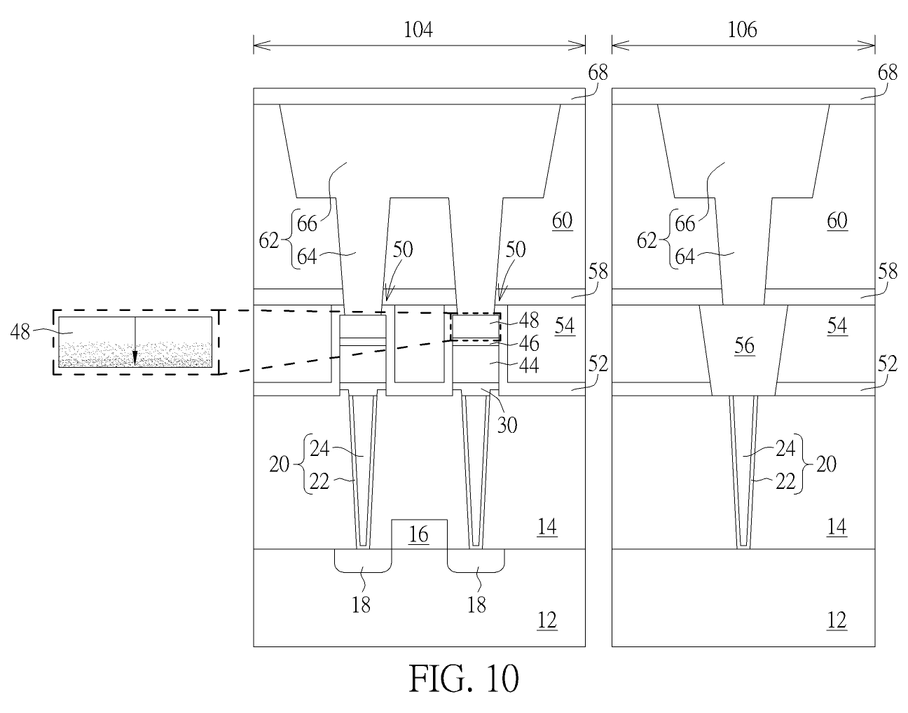

Referring to FIG. 10, FIG. 10 illustrates a structural view of a semiconductor device according to an embodiment of the present invention. As shown in FIG. 10, the top electrode 48 in this embodiment is a single layer structure, in which the bottom surface of the top electrode 48 directly contacts the capping layer 46, the top electrode 48 includes metal nitride such as TiN, and the top electrode 48 includes a gradient concentration of nitrogen. Specifically, the nitrogen concentration in the top electrode 48 is not evenly distributed as the nitrogen concentration within the top electrode 48 increases from top to bottom as indicated by the arrow in the figure. In other words, a higher concentration of nitrogen is found closer to the bottom surface of the top electrode 48 and a lower concentration of nitrogen is found closer to the top surface of the top electrode 48, or a lower concentration of Ti is found closer to the bottom surface of the top electrode 48 and a higher concentration of Ti is found closer to the top surface of the top electrode 48. By having a higher concentration of nitrogen closer to the bottom surface of the top electrode 48, it would be desirable to prevent TiOₓ from going through reduction oxidation reaction.

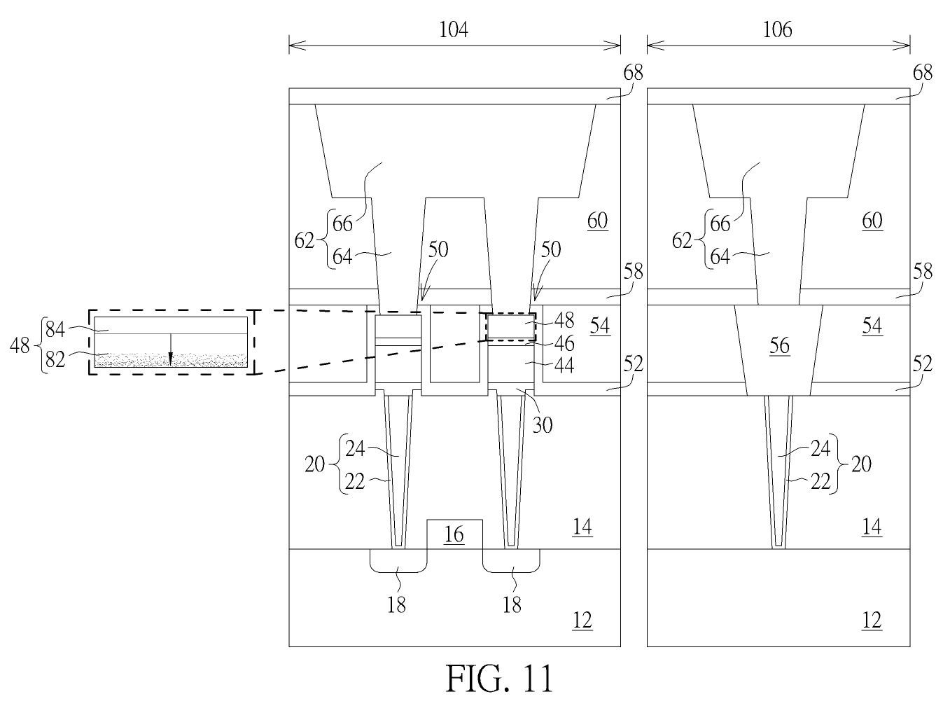

Referring to FIG. 11, FIG. 11 illustrates a structural view of a semiconductor device according to an embodiment of the present invention. As shown in FIG. 11, the top electrode 48 in this embodiment includes a first TE 82 and a second TE 84, in which the first TE 82 and the second TE 84 could include same thickness or different thickness, the bottom first TE 82 directly contacting the capping layer 46 includes metal nitride such as TiN and the top second TE 84 includes metal such as Ti, and the first TE 82 includes a gradient concentration of nitrogen. Similar to the top electrode 48 disclosed in FIG. 10, the nitrogen concentration in the first TE 82 of this embodiment is not evenly distributed as the nitrogen concentration within the first TE 82 increases from top to bottom as shown by the direction of the arrow in the figure. In other words, a higher concentration of nitrogen is found closer to the bottom surface of the first TE 82 and a lower concentration of nitrogen is found closer to the top surface of the first TE 82, or a lower concentration of Ti is found closer to the bottom surface of the first TE 82 and a higher concentration of Ti is found closer to the top surface of the first TE 82. By having a higher concentration of nitrogen closer to the bottom surface of the first TE 82, it would be desirable to prevent TiOₓ from going through reduction oxidation reaction as the Ti content of the upper second TE 84 could be used for lowering overall resistance of the device.

Overall, the present invention discloses an approach for fabricating RRAM device, which first forms contact plugs 20 in an ILD layer 14 to electrically or directly connecting active devices such as source/drain regions of a MOS transistor disposed on a substrate and then forms a RRAM 50 made of a bottom electrode 30, a resistor switching layer 44, a capping layer 46, and a top electrode 48 on the contact plugs 20. Preferably, the top electrode 48 could be made of a single layer structure or multi-layer structure, the top electrode 48 preferably includes metal nitride such as TiN, and the top electrode containing TiN could either include a gradient concentration of nitrogen (such as the embodiments shown in FIGS. 10-11) or not including a gradient concentration of nitrogen (such as the embodiments shown in FIGS. 7-9). By having metal or metal composite compound such as Ti and/or TiN or a TiN layer with gradient concentration of nitrogen in the top electrode, it would be desirable to reduce effectively reduce the occurrence of reduction oxidation reaction and also prevent titanium or nitrogen atoms from diffusing downward into the resistor switching layer thereby increasing overall performance of the device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A resistive random access memory (RRAM), comprising:
an interlayer dielectric (ILD) layer on a substrate;
a contact plug in the ILD layer;
a bottom electrode on the contact plug;
a resistor switching layer on the bottom electrode; and
a top electrode (TE) on the resistor switching layer, wherein the TE comprises more than one TE and the more than one TE comprises titanium nitride (TiN).

2. The resistive random access memory of claim 1, wherein the TE comprises:
a first TE on the resistor switching layer; and
a second TE on the first TE.

3. The resistive random access memory of claim 2, wherein the first TE comprises TiN and the second TE comprises titanium (Ti).

4. The resistive random access memory of claim 1, wherein the top electrode comprises:
a first TE on the resistor switching layer;
a second TE on the first TE; and
a third TE on the second TE.

5. The resistive random access memory of claim 4, wherein the first TE comprises TiN.

6. The resistive random access memory of claim 4, wherein the second TE comprises Ti.

7. The resistive random access memory of claim 4, wherein the third TE comprises TiN.

8. The resistive random access memory of claim 1, further comprising:
a capping layer adjacent to the top electrode;
a first inter-metal dielectric (IMD) layer around the capping layer;
a second IMD layer on the first IMD layer; and
a metal interconnection in the second IMD layer and connecting to the top electrode.

9. A resistive random access memory (RRAM), comprising:
an interlayer dielectric (ILD) layer on a substrate;
a contact plug in the ILD layer;
a bottom electrode on the contact plug;
a resistor switching layer on the bottom electrode; and
a top electrode (TE) on the resistor switching layer, wherein the top electrode comprises titanium nitride (TiN) having a gradient concentration of nitrogen.

10. The resistive random access memory of claim 9, wherein the TE comprises:
a first TE on the resistor switching layer; and
a second TE on the first TE.

11. The resistive random access memory of claim 10, wherein the first TE comprises TiN having a gradient concentration of nitrogen.

12. The resistive random access memory of claim 11, wherein the first TE comprises a higher concentration of nitrogen closer to a bottom surface of the first TE.

13. The resistive random access memory of claim 10, wherein the second TE comprises Ti.

14. The resistive random access memory of claim 9, wherein the TE comprises a single layer.

15. The resistive random access memory of claim 14, wherein the TE comprises a higher concentration of nitrogen closer to a bottom surface of the TE.
